(19) United States
(12) Patent Application Publication
(10) Pub. No.: US 2008/0203998 A1
(43) Pub. Date: Aug. 28, 2008

(54) ON-CHIP POWER SUPPLY MONITOR USING LATCH DELAY SENSOR

(75) Inventor: Keith A. Jenkins, Sleepy Hollow, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/680,115

(22) Filed: Feb. 28, 2007

(51) Int. Cl. G01R 23/14

(52) U.S. Cl. 324/76.41

(57) ABSTRACT

A system for on-chip power supply monitoring by using a single latch delay sensor, including a first delay chain; a second delay chain; a latch circuit; a latch counter; and a slate machine for controlling a voltage; wherein the one or more outputs of the first and second delay chains are compared via a digital logic circuit to detect transients above or below predetermined limits in a single clock cycle; and wherein the one or more outputs of the first and second delay chains are compared via a digital logic circuit to detect transients above or below predetermined limits in a single clock cycle; and wherein a ratio of (i) a number of signals counted by the latch counter and (ii) a number of signals counted by the clock counter yields a statistical measurement of the power supply or ground transients.

### TRADEMARKS

IBM® is a registered trademark of International Business Machines Corporation, Armonk, N.Y. U.S.A. Other names used herein may be registered trademarks, trademarks or product names of International Business Machines Corporation or other companies.

### BACKGROUND OF THE INVENTION

1. Field of the Invention

This invention relates to on-chip detection of power supply or ground noise, and particularly to an on-chip voltage or ground monitoring circuit that is used for detecting transients above or below pre-set limits in a single clock cycle or measuring a statistical distribution of power supply transients.

2. Description of Background

There are several problems concerning existing approaches for the on-chip detection of power supply or ground noise. Simultaneous switching transistors in densely packed circuits cause current spikes in power supply lines, which in turn cause voltage noise due to iR and Ldi/dt voltages. Similarly, power-gating methods, which interrupt power or ground result in transient or varying power or ground values after the power is restored. Transient overvoltages are large, very brief and potentially destructive increases in voltage. Transient undervoltages can lead to computation errors. On-chip measurements of such power supply fluctuations are important in understanding the power supply to which circuits are subjected to, and possibly used for control. For example, if the voltage to a chip or a sub-circuit of a chip falls below a certain level due to iR drop, the chip or sub-circuit might be operated more slowly, to draw less current, in order to restore the voltage.

Certain existing power supply noise detection techniques utilize some sort of direct or indirect analog voltage comparison or digitization. As a result, these techniques require carefully designed analog circuits, which depend on a stable fabrication process and accurate device models.

Considering the above limitations, it is desired to have an on-chip voltage or ground monitoring circuit that is used for detecting transients above or below pre-set limits in a single clock cycle and which does not require custom analog design.

### SUMMARY OF THE INVENTION

The shortcomings of the prior art are overcome and additional advantages are provided through the provision of a system comprising: a first delay chain for detecting power supply noise, the first delay chain having a first ring oscillator counter for calibration; a second delay chain being insensitive to the power supply noise, the second delay chain having a second ring oscillator counter for calibration; a system clock for driving the first and second delay chains via system clock signals, the system clock signals being counted by a clock counter; a latch circuit for receiving one or more outputs of the first and second delay chains; a latch counter for counting a number of outputs from the latch circuit; and a state machine for controlling a voltage that varies the delay of the second delay chain; wherein the one or more outputs of the first and second delay chains are compared via a digital logic circuit to detect transients above or below predetermined limits in a single clock cycle; and wherein a ratio of (i) a number of signals counted by the latch counter and (ii) a number of signals counted by the clock counter yields a statistical measurement of the power supply or ground transients.

The shortcomings of the prior art are overcome and additional advantages are provided through the provision of a method comprising: detecting power supply noise via a first delay chain, the first delay chain having a first ring oscillator counter for calibration; providing a second delay chain being insensitive to the power supply noise, the second delay chain having a second ring oscillator counter for calibration; driving the first and second delay chains via a system clock providing system clock signals, the system clock signals being counted by a clock counter; receiving one or more outputs of the first and second delay chains via a latch circuit; counting a number of outputs from the latch circuit; and controlling a voltage that varies the delay of the second delay chain via a state machine; wherein the one or more outputs of the first and second delay chains are compared via a digital logic circuit to detect transients above or below predetermined limits in a single clock cycle; and wherein a ratio of (i) a number of signals counted by the latch counter and (ii) a number of signals counted by the clock counter yields a statistical measurement of the power supply or ground transients.

Additional features and advantages are realized through the techniques of the present invention. Other embodiments and aspects of the invention are described in detail herein and are considered a part of the claimed invention. For a better understanding of the invention with advantages and features, refer to the description and the drawings.

### TECHNICAL EFFECTS

As a result of the summarized invention, technically we have achieved a solution for an on-chip voltage or ground monitoring circuit that is used for detecting transients above or below pre-set limits in a single clock cycle and which does not require custom analog design.

### BRIEF DESCRIPTION OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a schematic diagram of a delay chain apparatus for on-chip voltage/ground monitoring, in accordance with an embodiment of the invention;

FIG. 2 is a series of timing diagrams illustrating the operation of the delay chain apparatus of FIG. 1;

FIG. 3 is a schematic diagram of a circuit for measuring statistical distributions of voltages over a plurality of clock cycles, in accordance with an alternative embodiment of the invention;

FIG. 4 is a schematic diagram of a circuit for detecting single undershoot or overshoot voltages, in accordance with an alternative embodiment of the invention; and

FIG. 5 and FIG. 6 are a schematic diagram of a circuit performing calibration on a chip, in accordance with an alternative embodiment of the invention.

### DETAILED DESCRIPTION OF THE INVENTION

One aspect of the exemplary embodiments is an on-chip voltage or ground monitoring circuit, which can be used for detection of transients above or below pre-set limits in a single clock cycle. Another aspect of the exemplary embodiments is an on-chip voltage or ground monitoring circuit, which can measure a statistical distribution of power supply levels obtained over many clock cycles.

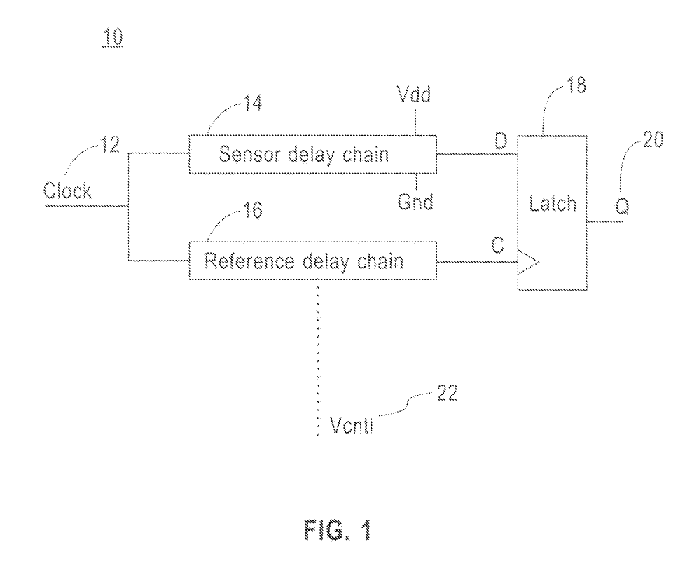

The basic mechanism of a power supply noise detector involves the use of two signal delay chains driven by the same system clock signal, as illustrated in FIG. 1. The circuit 10 of FIG. 1 includes a clock 12, a sensor delay chain 14, a reference delay chain 16, a latch circuit 18, an output 20, and a signal 22, Vcnt1.

The power supply noise detector 10 uses two delay chains 14, 16 driven by the same system clock signal 12. The reference delay chain 16 is designed to be insensitive to (or isolated from) power supply noise. In other words, the delay of the clock signal 12 through the reference delay chain 16 does not depend on power supply fluctuations, or it is connected to a known quiet power supply. For example, the reference delay chain 16 can be composed of differential buffer stages (not shown). The sensor delay chain 14 is a signal delay that is sensitive to power supply fluctuations, and it is connected to the power supply to be measure. The sensor delay chain 14 can be simple Complementary Metal Oxide Semiconductor (CMOS) inverters, or if more sensitivity is required, current-starved inverters, which are commonly used circuits for affecting delay with a control voltage.

The outputs of each chain 16, 14 are fed to the clock (‘C’) and data (‘D’) inputs of the latch circuit 18, respectively. The delay of the reference delay chain 16 is controlled by the voltage 22 Vcnt1, as established by the calibration procedure described below. This might be through the tail current control of a differential buffer or through the supply voltage of simple inverters. According to the timing of the clock 12, the latch circuit 18 either indicates a ‘1’ or a ‘0’. If the sensor delay chain 14 experiences a higher than normal supply (Vdd) while the signal is propagating, then its signal arrives earlier than the reference signal, and a “1” is stored in the latch circuit 18. If it experiences a lower than normal voltage (Vdd), then its signal arrive later than the reference signal and a “0” is stored in the latch circuit 18. The output of the latch circuit 18 is designated as Q (20). Thus the output 20 of the latch circuit 18 indicates the voltage state experienced by the signal delay chain 14 during the signal's propagation through the signal delay chain 14.

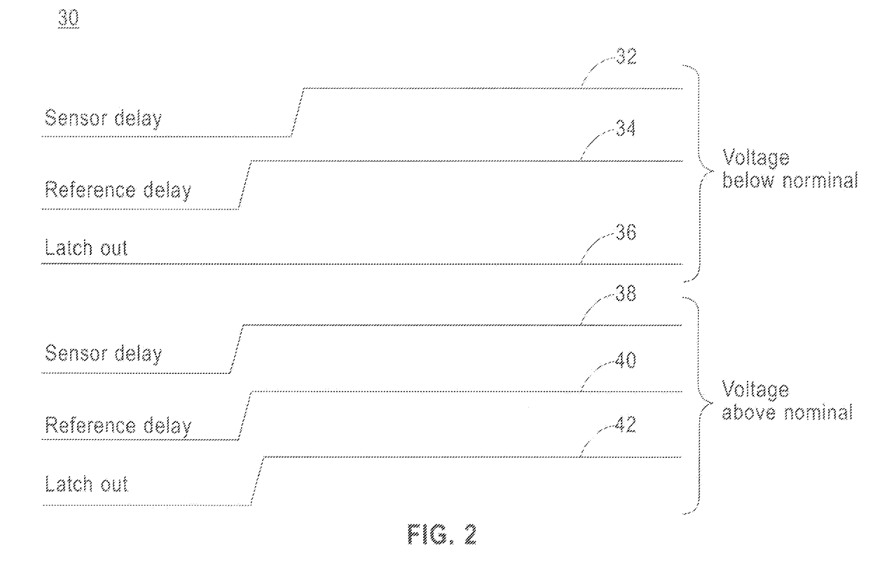

The function of the delay chains 14,16 of FIG. 1 as means to measure voltage as illustrated in FIG. 2. The functions 30 of FIG. 2 include, for the “voltage below,” a sensor signal 32, a reference signal 34, and a latch signal 36. The functions 30 for the “voltage above” include a sensor signal 38, a reference signal 40, and a latch signal 42. The “voltage below” is a lower than normal voltage (Vdd) supplied to the signal delay chain 14 and the “voltage above” is a higher than normal voltage (Vdd) provided to the signal delay chain 14. More generally, the voltage can refer either to the supply voltage Vdd or to the ground voltage applied to the signal delay chain 14. The voltage 22 (Vcnt1) may be a predetermined voltage value set by the manufacturer or may be a value set by the user. At a nominal voltage, the sensor delay signal 32 and the reference delay signal 34 are equal.

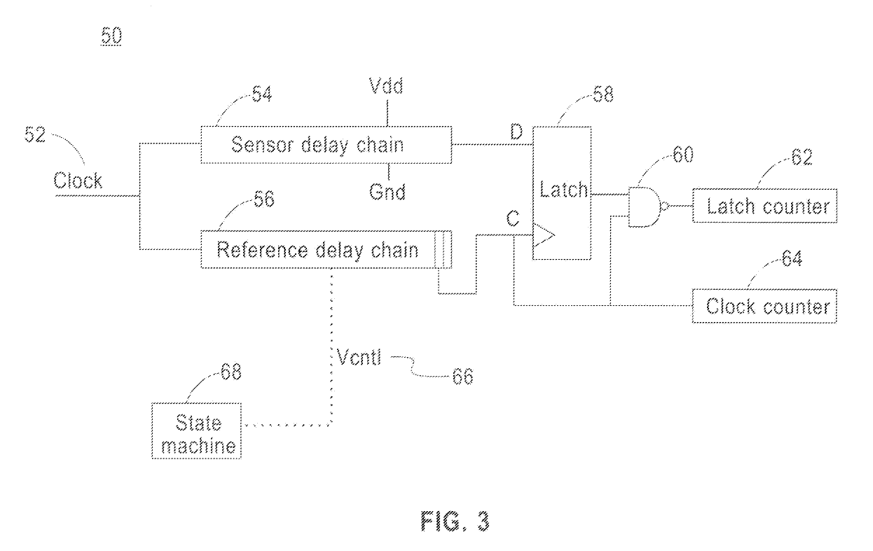

To use a measurement circuit to measure statistical distribution of voltage over many clock cycles, the circuit of FIG. 1 is configured as shown in FIG. 3. FIG. 3 illustrates an example of a circuit for measuring statistical distributions of voltages over a plurality of clock cycles. The circuit 50 of FIG. 3 includes a clock 52, a sensor delay chain 54, a reference delay chain 56, a first latch 58, a NAND gate 60, a latch counter 62, a clock counter 64, a voltage control signal 66 (Vcnt1), a state machine 68.

The voltage control signal 66, Vcnt1, is set by a state machine 68 to intentionally vary the delay of the reference delay chain 56. Alternatively, the number of stages in the reference delay chain 56 can be varied. As the delay of the “C” signal is varied, more or fewer of the “D” signals result in the latch having a “1” output. As the delay is swept by Vcnt1 or by the number of delay stages used, the number of “1”s. function of the delay is counted by the latch counter 62. The NAND gate 60 following the latch curcuit 58 forces tha latch counter 62 to toggle in the case of successive “1”s. The clock counter 64 counts every system clock signal going through the latch circuit 58. Hence, the ratio of latch counter 62 counts to clock counter 64 counts indicates the number of times a “1” is formed. As the delay is swept, this ratio becomes the cumulative distribution function of the power supply voltage as a function of the control voltage 66, Vcnt1. The derivative of this function is the original distribution function, which is the quantity to be measured in this technique. If the function is measured by varying the number of stages in the reference delay chain 56, then an additional calibration step is utilized, as described below.

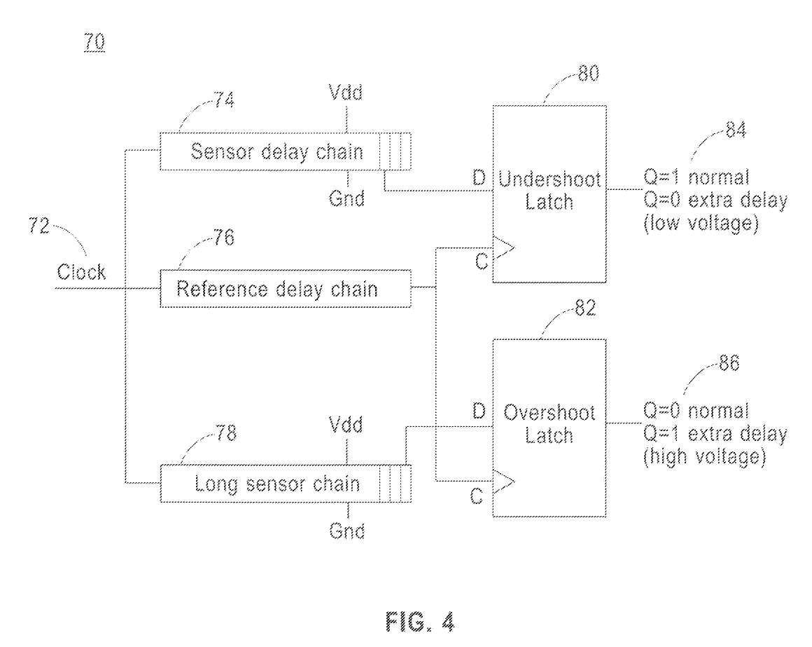

To detect single undershoot or overshoot voltages, the circuit of FIG. 3 is configured as shown in FIG. 4. The circuit 70 of FIG. 4 includes a clock 72, a short sensor chain 74, a reference delay chain 76, a long sensor chain 78, an undershoot latch 80, and an overshoot latch 82. The output of the undershoot latch 80 is designated as 84, when a low voltage is detected. The output of the overshoot latch 82 is designated as 86, when a high voltage is detected. A voltage Vdd is “low” if its value is below the nominal voltage and a voltage Vdd is “high” if its value is above the nominal voltage.

If undershoot and overshoot detection are desired, two voltage-sensitive chains are used, as shown. The undershoot chain is a short sensor chain 74, so that ordinarily its signal arrives at the latch before the clock signal 72 and registers a “1”. If its voltage is sufficiently low during the propagation time, its signal is late at the undershoot latch 80, and a “0” is registered. The length of chain used for the voltage undershoot detection can be selected as needed. Similarly, an overshoot chain is long enough so its signal is late at the latch, registering a “0”. The overshoot chain is the reference delay chain 76 and the long sensor chain 78. If the voltage goes high enough, its signal arrives earlier, and registers a “1” indicated an overshoot during the measurement time. Similarly, the length of chain determines the voltage thresholds for voltage detection. For either undershoot or overshoot signals, the undershoot latch 80 output and the overshoot latch output 82 indicate either a logic “1” or “0” occurring during a single clock cycle, that is, it makes a single cycle determination of voltages crossing the set thresholds. If the two delay chains have the same sensitivity to voltage, the above-described measurement would be a direct mapping of the power supply voltage into control voltage units. In general, however, the chains have different delay vs. voltage functions, and a calibration might be required.

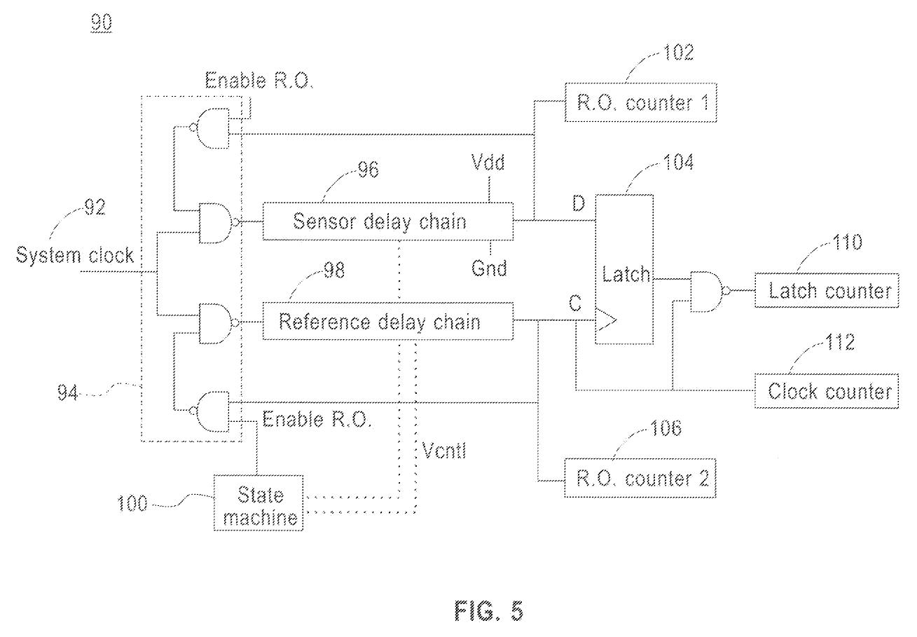

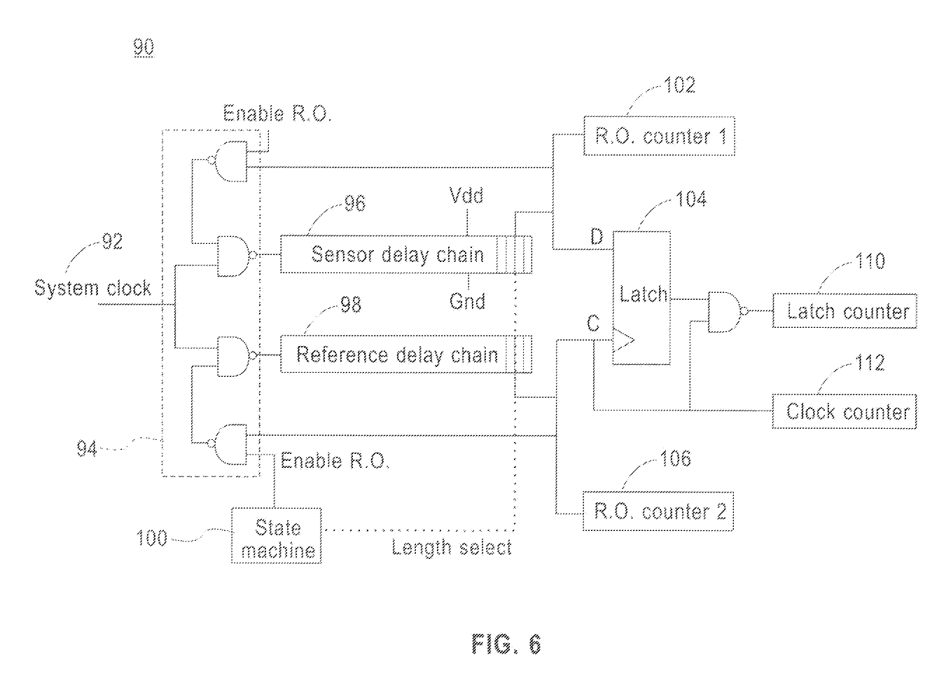

FIGS. 5 and 6 illustrate one example of a circuit performing calibration on a chip. The circuit 90 in FIGS. 5 and 6 include a system clock 92, a series of NAND gates 94, a sensor delay chain 96, a reference delay chain 98, a state machine 100, a first counter 102, a latch 104, a second counter 106, a latch counter 110, and a clock counter 112.

To establish a voltage calibration, each delay chain 96, 98 can be configured as a ring oscillator (RO) by setting the enable RO signal high or “1”. When this occurs, the number of oscillating signals through the chains 96, 98 is counter by the RO counters 102, 106. At the same time, the clock counter 112 counts the system clock signals. The ratio of counts yields the ratio of the chain ring oscillators to the system clock, and the delay through the chains is computed from this ratio and from the known period of the system clock. A state machine 100 controls the calibration process. If voltage control, Vcnt1, of delay is used as described in FIGS. 2-4, then, as seen in FIG. 5, by sweeping the control voltages Vcnt1 ad Vcnt1_sig, the delay through each chain 96, 98 is obtained as a function of voltage, resulting in a calibration curves of delay vs. voltage. If delay is controlled by selecting the number of delay elements used in the delay chain, then, in addition, the delay through each chain 96, 98 is obtained as a function of number of delay elements, as indicated by FIG. 6. Applying these calibrations to the measurement, the distribution of measured voltages is obtained as a function of the ratios of the slopes of the two calibration curves.

Therefore, the exemplary embodiments described an on-chip voltage or ground monitoring circuit, which can be used in the following two ways: 1) measuring a statistical distribution of power supply levels obtained over many clock cycles, or 2) for detecting transients above or below pre-set thresholds in a single clock cycle. As a result, the embodiments disclosed herein employ a voltage to time converter, and make a time comparison through a digital logic circuit. Hence, the methodology is inherently digital, requiring no analog voltage sensing circuits, and only a simple digital calibration to establish the voltage-to-time calibration, making the sensor inherently much less sensitive to process variations and the design less dependent on accurate device models than alternate measurement methods.

The capabilities of the present invention can be implemented in software, firmware, hardware or some combination thereof.

As one example, one or more aspects of the present invention can be included in an article of manufacture (e.g., one or more computer programs products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

While the preferred embodiment to the invention has been described, it will be understood that those skilled in the art, both now and in the future, may make various improvements and enhancements which fall within the scope of the claims which follow. These claims should be construed to maintain the proper protection for the invention fist described.

What is claimed is:

1. A system for on-chip power supply monitoring by using a single latch delay sensor, the system comprising:
a first delay chain for detecting power supply noise, the first delay chain having a first ring oscillator counter for calibration only;
a second delay chain being insensitive to the power supply noise, the second delay chain having a second ring oscillator counter for calibration only;
a system clock for driving the first and second delay chains via system clock signals, the system clock signals being counted by a clock counter;
a latch circuit for receiving one or more outputs of the first and second delay chains;
a latch counter for counting a number of outputs from the latch circuit; and
a state machine for controlling a voltage that varies the delay of the second delay chain;
wherein the one or more outputs of the first and second delay chains are compared via a digital logic circuit to detect transients above or below predetermined limits in a single clock cycle; and
wherein a ratio of (i) a number of signals counted by the latch counter and (ii) a number of signals counted by the clock counter yields a statistical measurement of the power supply or ground transients.

2. The system of claim 1, wherein the output of the sensor delay chain is one or more data signals.

3. The system of claim 1, wherein the output of the reference delay chain is one or more clock signals.

4. A method for on-chip power supply monitoring by using a single latch delay sensor, the method comprising:
detecting power supply noise via a first delay chain, the first delay chain having a first ring oscillator counter for calibration only;
providing a second delay chain being insensitive to the power supply noise, the second delay chain having a second ring oscillator counter for calibration only;
driving the first and second delay chains via a system clock providing system clock signals, the system clock signals being counted by a clock counter;
receiving one or more outputs of the first and second delay chains via a latch circuit;
counting a number of outputs from the latch circuit; and
controlling a voltage that varies the delay of the second delay chain via a state machine;
wherein the one or more outputs of the first and second delay chains are compared via a digital logic circuit to detect transients above or below predetermined limits in a single clock cycle; and
wherein a ratio of (i) a number of signals counted by the latch counter and (ii) a number of signals counted by the clock counter yields a statistical measurement of the power supply or ground transients.

5. The method of claim 4, wherein the output of the sensor delay chain is one or more data signals.

6. The method of claim 4, wherein the output of the reference delay chain is one or more clock signals.
